(19) United States
(12) Patent Application Publication
(10) Pub. No.: US 2012/0074380 A1
(43) Pub. Date: Mar. 29, 2012

(54) WHITE LIGHT EMITTING DIODE

(75) Inventors: Jyh-Shyang Wang, Chung-Li City (TW); Wei-Jie Chen, Chung-Li City (TW); Wei-Hsuan Lo, Chung-Li City (TW); Ren-Hao Chen, Chung-Li City (TW)

(73) Assignee: CHUNG YUAN CHRISTIAN UNIVERSITY, Tao-Yuan (TW)

(21) Appl. No.: 13/246,032

(22) Filed: Sep. 27, 2011

(30) Foreign Application Priority Data
Sep. 27, 2010 (TW) 099132668

(51) Int. Cl. H01L 33/04; H01L 33/28

(52) U.S. Cl. 257/13; 438/47; 257/E33.008; 257/E33.021

(57) ABSTRACT

A white light emitting diode (LED) and method for forming the white LED are provided, wherein a semiconductor material is formed directly with a epitaxial method on a GaN epitaxial structure. The semiconductor material is a doped II-VI semiconductor compound with a broad FWHM (Full Width at Half Maximum) compared to conventional phosphor, can provide a white LED with better color rendering.

### BACKGROUND OF THE INVENTION

1. Field of the Invention

The present invention is related to a multi-wavelength light emitting diode (LED) and fabrication method thereof, and more particularly to a single-chip, white light LED and fabrication method thereof.

2. Description of the Prior Art

Taiwan is currently the second largest manufacturer of light emitting diodes around the world, and, in the new application of LED, also has a very advanced technology, wherein illumination is very likely to be the most future application market. At this stage, white light illumination is one of the key development technologies in the world, and that is a very important part in the energy policies. After developed the green light LED and the blue light LED, the first provided white LED is to combine three LEDs with red, green and blue lights. However, because of the difference of each LED in electric properties and life, this manner could not provide a stable white LED.

The Japanese's LED manufacture, Nichia, has the most mature technology by exciting yellow phosphor with a blue LED to fabricate the current white LED. However, such technology will obtain a narrow white light spectrum with worse color render index. Furthermore, due to some problems of stability of phosphor materials and patent issues, there are many new foreign and domestic ideas and technologies proposed successively, and proceeding to research and development.

A method is to excite multiple phosphors to acquire white light. It is proposed mainly by C. C. Yang, C. M. Lin, Y. J. Chen, Y. T Wu, S. R. Chuang, R. S. Liu and S. F. Hu in Appl. Phys. Lett. Vol. 90, 123503, (2007), and the InGaN blue LED excites the green phosphor SrSi₂O₂N₂:Eu and the red phosphor CaSiN₂:Ce. In addition, the method proposed by Y. H. Won, H. S. Jang, W. B. Im, D. Y. Jeon and J. S. Lee in Appl. Phys. Lett. Vol. 89, 231909, (2006) and by W. J. Yang and T. M. Chen in Appl. Phys. Lett. Vol. 88, 101903, (2006), is to use ultraviolet LED to excite red, green and blue color phosphors. However, the efficiently of the red phosphor is poor presently, and the progress of color rendering index is unapparent. Hence, the method is less adopted in the mainstream commercial applications.

Another way is to use blue LED to excite a cover layer with CdSe/ZnS quantum dot materials. For example, H. S. Chen, D. M. Yeh, C. F. Lu, C. F. Huang, W. Y. Shiao, J. J. Huang, C. C. Yang, I. S. Liu and W. F. Su etc., proposed in IEEE photonics Technol. Lett. Vol. 18, No. 13, 1430, (2006), use InGaN to emit blue light, GaN to emit green light, and CdSe/ZnS nanocrystals as the red light source. S. Nizamoglu, E. Mutlugun, T. Ozel, H. V. Demir, S. Sapra, N. Gaponik, and A. Eychmüller etc., proposed in Appl. Phys. Lett. Vol. 92, 113110, (2008) use InGaN to emit blue light and (CdSe)ZnS/CdSe quantum dot as the yellow light source. However, the epitaxial lattice mismatch between nitrides and Group II-VI still exists, and epitaxial lattice still incur defects in the crystal, to cause the lower luminous efficiency and product life.

Another way is to directly emit white light by using single-chip LED without the use of phosphor. In Appl. Phys. Lett. Vol. 84, 672, (2004), D. Xiao, K. W. Kim, S. M. Bedair, and J. M. Zavada etc. propose three InGaN/AlInGaN quantum well structures and emitting red, blue and green three primary colors at the same time. In Appl. Phys. Lett. Vol. 92, 081107, (2008), S. N. Lee, H. S. Paek, H. Kim, T. Jang, and Y. Park etc. propose an indium-phase separated InGaN/GaN single quantum well structure being able to excite green and amber light by using blue InGaN/GaN multiple quantum well structures. In Appl. Phys. Lett. Vol. 90, 151122, (2007), C. F. Huang, C. F. Lu, T. Y. Tang, J. J. Huang, and C. C. Yang etc. propose the use of InGaN/GaN multiple quantum well structure to excite blue light and InGaN/GaN multiple quantum well structure to excite yellow light. In Appl. Phys. Lett. Vol. 91, 161912, (2007), X. H. Wang, H. Q. Jia, L. W. Guo, Z. G. Xing, X, J, Pei, J. M. Zhou, and H. Chen etc. propose the use of InGaN/GaN multiple quantum well structures to excite blue light and the quantum dots containing In-rich to excite yellow light. In Appl. Phys. Lett. Vol. 90, 161115, (2007), Y. J. Lee, P. C. Lin, T. C. Lu, H. C. Kuo, and S. C. Wang etc. propose the use of laser lift-off (LLO) and wafer-bonding technologies to bond the blue LED together with the green LED. In Appl. Phys. Lett. Vol. 92, 013507, (2008), X. Guo, G. D. Shen, B. L. Guan, X. L. Gu, D. Wu, and Y. B. Li etc. propose the use of GaAs/GaN heterojunction direct wafer bonding technology. In IEEE Photonics Technol. Lett. Vol. 18, No. 24, 2593, (2006), J. W. Shi, H. Y. Huang, C. K. Wang, J. K. Sheu, W. C. Lai, Y. S. Wu, C. H. Chen, J. T. Chu, H. C. Kuo, W. P. Lin, T. H. Yang, and J. I. Chyi etc. propose the use of directly epitaxial technology to form green and blue InGaN multiple quantum well layer.

Nitride material system is the mainstream material of blue light and ultraviolet, and has more industry's advantages, so most groups proceeding to study and research single-chip white LED have chosen the InGaN material system. However, it needs very high composition of indium to produce the red light within InGaN materials. This method usually incurs many material defects, and brings lower luminous efficiency. The current epitaxial technology can only produce approximately a yellow light. Even though provisionally it is not considered the problems of luminous efficiency, other problems of color temperature and poor color rendering still exist. Hence, for the warm temperature and high color rendering of single-chip white LED technology, the red light epitaxial technology still has a lot of problems to be overcome, and the difficulty is quite high.

Another technology, please refer to the U.S. Pat. No. 6,919,582 filed by Chen, which proposes a method for growing nitride materials on ZnTe or ZnSe substrate. The blue light is emitted by the nitrides and then absorbed by the substrate. Finally the yellow-green light is excited. However, this way does not really bring a red light, and the epitaxial quality is also a great test. Furthermore, please refer to the U.S. Pat. No. 6,825,498 filed by Lai et al., it proposes using ZnSe blue LED to excite green phosphors, combined with the yellow light emitted by the internal defects in the ZnSe substrate to result in the white light. Similarly, it cannot bring real red light.

At present, the technology of manufacturing single-chip white LED is most critical and with greatest risks. Currently, foreign and domestic technologies are still only in the initial trial stage. The latest related literatures report that the epitaxial material issues result in a poor luminous efficiency of the above LED without using phosphor. However, once the technology successfully develops in the future, in terms of cost, patents, technical superiority and so far, it is most competitive.

### SUMMARY OF THE INVENTION

In view of the above mentioned invention background, in order to comply with industry demand and achieve the foregoing purpose, the present invention provides a white light emitting diode, which comprises a GaN multilayer structure and a photon energy conversion layer. The above mentioned GaN multilayer structure is used to emit the first wavelength of visible light. The foregoing photon energy conversion layer comprises II-VI semiconductor compounds which includes (ZnₓCd₁₋ₓ)(O_{y}Se_{z}Te_{1-y-z}) doped with element of Group III, Group V or Group VII, wherein 0≦x, y, z≦1. The photon energy conversion layer emits the second wavelength of visible light after absorbing the first wavelength of visible light, such that the first wavelength and the second wavelength are mixed and emit a white light, wherein the second wavelength is longer than the first wavelength.

Full-width at half maximum (FWHM) of an emission spectrum of the photon energy conversion layer closes to FWHM of an emission spectrum of a conventional phosphor in the present invention. The above mentioned doping element of Group III can be indium or gallium, the doping element of Group V can be nitrogen, phosphorus, arsenic or antimony, and the doping element of Group VII is chlorine or iodine.

The foregoing II-VI semiconductor compound is a film including (ZnₓCd₁₋ₓ)(O_{y}Se_{z}Te_{1-y-z}) in the present invention, wherein the II-VI semiconductor compound is mixed with mono-layer quantum dot or multi-layer quantum dot.

A method of forming a white LED is provide in this invention, which comprises a step of providing a GaN multilayer structure, and forming a photon energy conversion layer upon the GaN multilayer structure. The foregoing GaN can emit a first wavelength of visible light. The above mentioned photon energy conversion layer comprises II-VI semiconductor compounds which include (ZnₓCd₁₋ₓ)(O_{y}Se_{z}Te_{1-y-z}) doped with element of Group III, Group V or Group VII, wherein 0≦x, y, z≦1. The photon energy conversion layer emits the second wavelength of visible light after absorbing the first wavelength of visible light, such that the first wavelength and the second wavelength are mixed and emit a white light, wherein the second wavelength is longer than the first wavelength.

In the present invention of the method for forming a white LED, the photon energy conversion layer is formed by using molecular beam epitaxial method or metal organic chemical vapor deposition method.

In the present invention of the method for forming a white LED, the foregoing the doping element of Group III can be indium or gallium, the doping element of Group V can be nitrogen, phosphorus, arsenic or antimony, and the doping element of Group VII can be chlorine or iodine.

In the present invention of the method for forming a white LED, the foregoing II-VI semiconductor compound is a film including (ZnₓCd₁₋ₓ)(O_{y}Se_{z}Te_{1-y-z}), wherein the II-VI semiconductor compound is mixed with mono-layer quantum dot or multi-layer quantum dot.

### BRIEF DESCRIPTION OF THE DRAWINGS

FIG. 1 is a structure diagram of a conventional LED.

FIG. 2 is a structure diagram of LEDs with a photon energy conversion layer in the present invention.

FIG. 3 is a structure diagram of LEDs with a photon energy conversion layer after grain cutting in the present invention.

FIG. 4 is a spectrum diagram of a white LED with a photon energy conversion layer in the present invention and a general conventional LED with yellow phosphor.

### DESCRIPTION OF THE PREFERRED EMBODIMENTS

The explored direction in the present invention is related to a multi-wavelength LED or white LEDs. In order to thoroughly understand the present invention, steps and composition will be presented in the following detailed description. Clearly, the execution of the present invention is not limited to special details of multi-wavelength LEDs or white LEDs that skills are familiar with. On the other hand, the composition and steps as known to all are not described in detail to avoid unnecessary restrictions in the present invention. Preferred embodiments of the present invention are described in detail below, but in addition to those descriptions, the present invention can still be widely executed in other embodiments, and the scope of the present invention is not limited to, subjects to later scope of the patent.

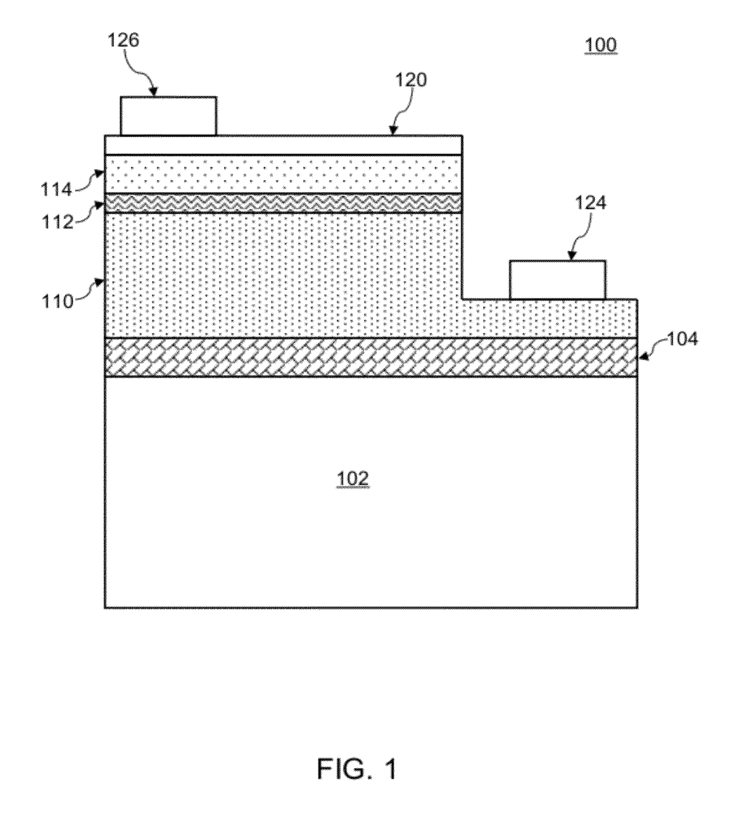

FIG. 1 is a structure diagram of a conventional LED 100, wherein a low-temperature buffer layer 104 is formed on a substrate 102, wherein the substrate can be sapphire substrates, silicon carbide substrates, gallium nitride substrates or zinc oxide substrates etc. If the gallium nitride multilayer structure has a larger difference of lattice constant, such lattice mismatch, to substrate 102, it will cause the GaN layer unable to be directly grew on the substrate 102, and hence the low-temperature buffer layer 104 needs to be formed firstly. For general commercial manufactures, the low-temperature buffer layer 104 needs to be formed on the sapphire substrate or the silicon carbide substrate.

Later, on the low-temperature buffer layer 104, a first conductive semiconductor layer 110, a light-emitting layer 112 and a second conductive semiconductor layer 114 are formed sequentially, and the three layers are the structures of a LED. The foregoing first conductive semiconductor layer 110, the light-emitting layer 112 and the second conductive semiconductor layer 114 are the structures of GaN, and for the demand of electrical conductivity, they are doped with conductive elements of n-type or p-type. Generally, the first conductive semiconductor layer 110 is usually n-type conductive GaN structures or n-type conductive AlGaN structures, and generally the second conductive semiconductor layer 114 is p-type conductive GaN structures or p-type conductive AlGaN structures, and vice versa. The n-type conductive doping elements are usually atoms of Group IV, preferred silicon, and p-type conductive doping elements are usually atoms of Group II, preferred magnesium or zinc. The light-emitting layer 112 can be a structure of multiple quantum wells (MQW), wherein the barrier layer of the quantum well can be AlGaN, and the quantum well layer can be InGaN. The foregoing manufacture process of forming structures of LED can be molecular beam epitaxy (MBE) or metal-organic chemical vapor deposition (MOCVD).

After the epitaxial process is finished, a portion is removed from the LED structure if sapphire substrate is used, and then a portion of the first conductive semiconductor layer is exposed, because of the nonconductive sapphire substrate. At this time, a first electrode 124 and a second electrode 126 are formed on the first conductive semiconductor layer 110 and on the second conductive semiconductor layer 114 respectively. If the electrical conductivity of the second semiconductor layer 114 is p-type, a p-type ohmic contact layer 120 should be formed first on the second conductive semiconductor layer 114.

As shown in FIG. 1, it is a LED die after dicing. If a white LED is to be formed, in the following package process, phosphors are mixed into a transparent plastic material. However, this kind of LEDs has many shortcomings. In the present invention, after the LED structure is formed, a photon energy conversion layer continues being formed by using epitaxial process.

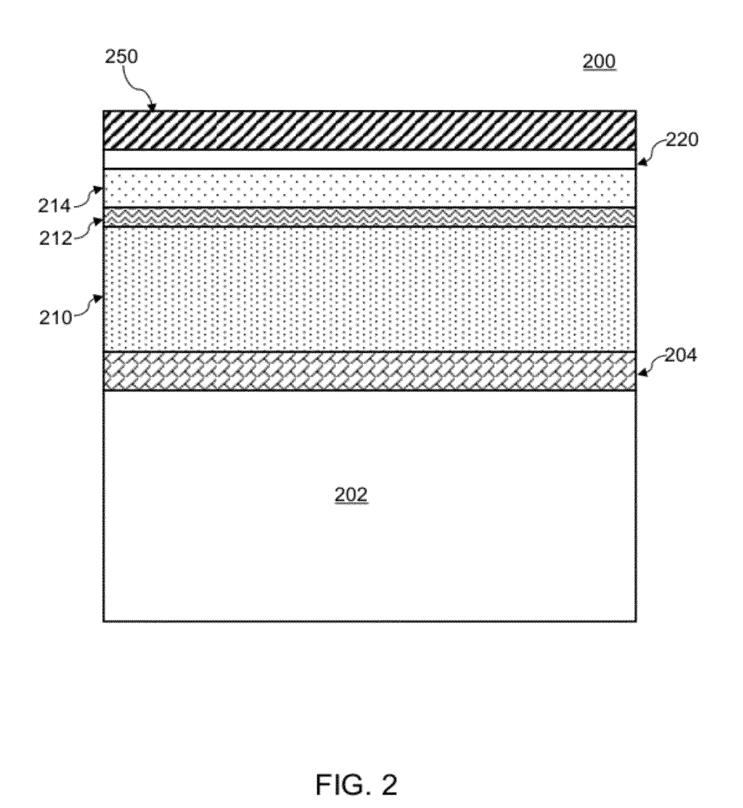

As shown in FIG. 2, it shows a structure diagram of a white LED 200 with a photon energy conversion layer. First, a low-temperature buffer layer 204 is formed on a substrate 202. Later, a first conductive semiconductor layer 210, a light-emitting layer 212 and a second conductive semiconductor layer 214 are sequentially formed on the low-temperature buffer layer 204. The foregoing manufacture of LED is essentially the same as the epitaxial process of conventional LED structures in FIG. 1, and it can be molecular beam epitaxy or metal-organic chemical vapor deposition method. To form a white LED, emitting frequencies of the light-emitting layer 212 are in the range of 410 nm to 460 nm.

Later, a photon energy conversion layer 250 is formed on the second conductive semiconductor layer 214 by using molecular beam epitaxy or metal-organic chemical vapor deposition method, wherein the photon energy conversion layer 250 includes II-VI semiconductor compounds of (ZnₓCd₁₋ₓ)(O_{y}Se_{z}Te_{1-y-z}) doped with elements of Group III, Group V or Group VII, wherein 0≦x, y, z≦1. The foregoing doping element of Group III can be indium or gallium, the doping element of Group V can be nitrogen, phosphorus, arsenic or antimony, and the doping element of Group VII can be chlorine or iodine. The foregoing II-VI semiconductor compound is a film including (ZnₓCd₁₋ₓ)(O_{y}Se_{z}Te_{1-y-z}), wherein the II-VI semiconductor compound is mixed with mono-layer quantum dot or multi-layer quantum dot. The preferred embodiment is ZnSe epitaxial layer highly doped with chlorine (Cl), wherein the doping concentration is about 10¹⁹ cm⁻³ above. The formation temperature of ZnSe epitaxial layer is about 300 to 350° C., and the thickness is about tens to hundreds of nm. Because ZnSe layer has a very high concentration of free electrons (more than 10¹⁹ cm⁻³), after the ZnSE is excited by blue light to generate electrons and holes, a portions of holes is very easy to find and compensate with most electrons and to emit light. Thus, although the lattice mismatch will result in dislocation defects, but the luminous efficiency is still quite high enough. In addition, within the bandgap of Cl-doped ZnSe materials, there are very much impurity defect energy levels of different energy states, resulting in the emission wavelength close to yellow orange light, and the wavelength distribution is very wide, which can be called the self-activated (SA) light in the papers; please referring to A. E. Martineź-Cantoń, M. Garciá-Rocha, I. Hernandeź-Calderoná and R. Ortega-Martmez\acute{b}, Microelectronics Journal, Vol. 36, 527, (2005).

A buffer layer 220 can be formed between the second conductive semiconductor layer 214 and the photon energy conversion layer 250, wherein its material is the high doped ZnO formed by using molecular beam epitaxy or metal-organic chemical vapor deposition method with the formation temperature between about 500 to 800° C. and the thickness about several nano meters.

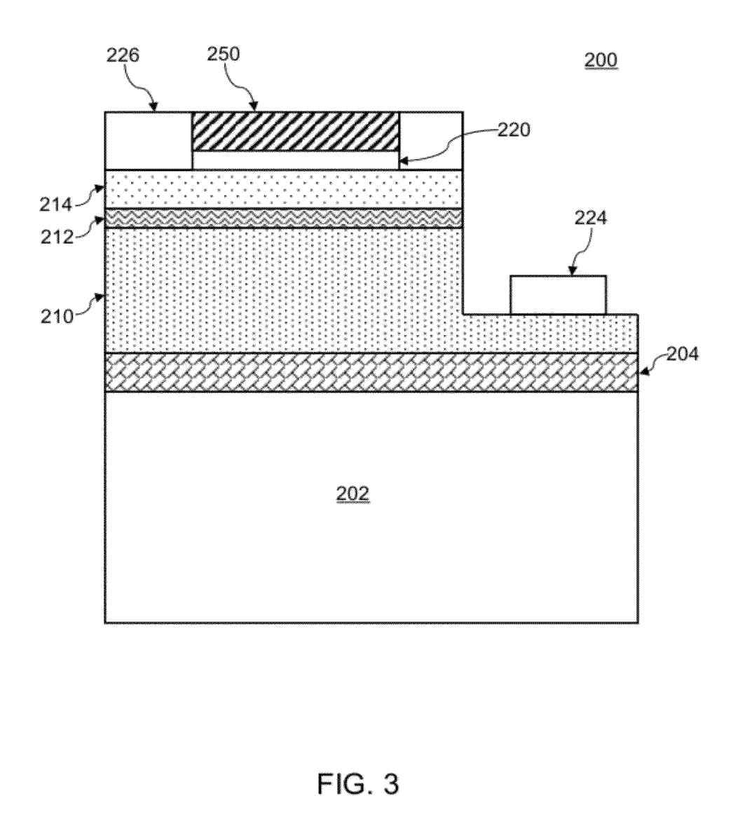

In the following step of performing a dicing process, the results can be shown in FIG. 3. First a portion of photon energy conversion layer 250 and a portion of GaN LED structure are removed, and the first conductive semiconductor layer 210 is thus exposed. Then, a first electrode 224 and a second electrode 226 are respectively formed on the first conductive semiconductor layer 210 and the second conductive semiconductor layer 214. It is noteworthy that the second electrode 226 is directly located on the second conductive semiconductor layer 214, which means the photon energy conversion layer 250 is nonconductive. For the photon energy conversion layer 250, it is very important, because the ZnSe epitaxial layer highly doped with Cl has many defects, and when electric current passes through the material, those defects will decrease the life of photon energy conversion layer 250, and then the luminous efficiency will continually decay. For the concern of mixing lights, there will be life problems.

For general epitaxial conductions, the first conductive semiconductor layer 210 is n-type conductive layer, while the second conductive semiconductor layer 214 is p-type conductive layer. Currently, in some dicing processes, the bottom of the sapphire substrate is removed, and another substrate upon the p-type conductive layer is formed. Then, the n-type conductive layer and the p-type conductive layer will be reversed in order. Therefore, as shown in FIG. 3, the first conductive semiconductor layer 210 can also be a p-type conductive layer, while the second conductive semiconductor layer 214 can also be a n-type conductive layer. FIG. 3 is a traditional electrode structures in the same plane, in which the first electrode 224 and the second electrode 226 are facing the same side. If the substrate 220 is conductive, then the first electrode 224 can be formed below the substrate 202.

Generally, an ohmic contact layer will be formed between the p-type conductive layer and the electrode. This technology can be referred to some other prior art.

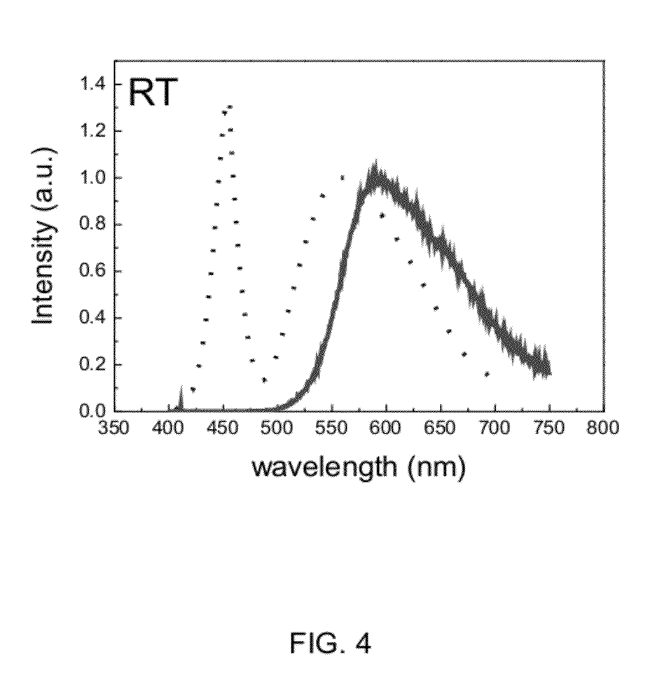

FIG. 4 is a spectrum diagram of a white LED with a photon energy conversion layer in the present invention compared with the spectrum diagram of a general conventional white LED with yellow phosphor, wherein X axis is the light wavelength and the Y axis is the light intensity. The two dotted line peaks are the luminous spectrum of a general blue LED and a white LED with yellow phosphor respectively, wherein, the left peak, at about 450 nm, is the luminous spectrum of general blue LED, while the right peak, at about 570 nm, is the luminous spectrum of white LED with yellow phosphor. The solid line is the luminous spectrum of a white LED with a photon energy conversion layer in the present invention, the light color is yellow orange, the wavelength is about 590 nm, and the full width at half maximum (FWHM) is closes to that of a conventional white LED with yellow phosphor. General photon energy conversion layers, owing to restrictions of the light-emitting mechanism, the luminous spectrum is close to that of general LEDs, while the white light produced by mixing light has a poor color rendering. In FIG. 4, in order to facilitate comparison, the spectrum lines of blue LEDs and commercial white LEDs with yellow phosphor are put together, and to make the peak of commercial white LEDs with yellow phosphor as the base to normalize them. In the present invention, light-mixing conditions can be determined by the wavelength of GaN LEDs, the doping concentration of the photon energy conversion layer, and the thickness of the photon energy conversion layer.

Conventional white LEDs with yellow phosphor to perform the light-mixing will be carried out in the package process. As the complex of yellow phosphors is not easy to be formed, and the life of white LEDs with yellow phosphor is inferior to that of GaN LEDs, hence for mass production, there exist some problems, such as uneven color coordinate, and the recession of phosphors will reduce the life of whole white LED. In addition, the phosphors have the shortcomings of poor heat resistance and easily being damped; that will more reduce the application possibility of white LEDs. The luminous spectrum of general photon energy conversion layers is too narrow, and its FWHM is very close to general LEDs, that would result in color rendering failure for white LEDs, and these disadvantages cause the white LEDs not to be suitable for LCD backlight, or can't as a auxiliary source for cameras.

The photon energy conversion layer in the present invention, due to its fabrication process, is similar to epitaxial conductions of GaN, and even can be produced in the same epitaxial chamber, wherein its heat resistance and moisture resistance are better than most phosphors. In addition, step of the light-mixing can be determined in the epitaxial process, which will gain more accuracy than prior phosphor mixing process in the package process. Furthermore, the photon energy conversion layer is formed by using the epitaxial method, and its life is longer than phosphors. Compared to other photon energy conversion layer, the photon energy conversion layer in the present invention is formed by using highly doped II-VI semiconductor compounds, which will cause FWHM close to that of phosphors and to emit yellow orange light, and can effectively provide a white LED with better color rendering.

Obviously many modifications and variations are possible in light of the above teachings. It is therefore to be understood that within the scope of the appended claims the present invention can be practiced otherwise than as specifically described herein. Although specific embodiments have been illustrated and described herein, it is obvious to those skilled in the art that many modifications of the present invention may be made without departing from what is intended to be limited solely by the appended claims.

What is claimed is:

1. A white light emitting diode (LED) comprising:
a GaN multilayer structure, emitting a first wavelength of visible light; and
a photon energy conversion layer, composing of II-VI semiconductor compounds including (ZnₓCd₁₋ₓ)(O_{y}Se_{z}Te_{1-y-z}) doped with element of Group III, Group V or Group VII, wherein 0≦x, y, z≦1, the photon energy conversion layer emitting a second wavelength of visible light after absorbing said first wavelength of visible light, such that the first wavelength and the second wavelength are mixed and emit a white light, wherein the second wavelength is longer than the first wavelength.

2. The white LED according to claim 1, wherein full-width at half maximum (FWHM) of an emission spectrum of the photon energy conversion layer closes to FWHM of an emission spectrum of a conventional phosphor.

3. The white LED according to claim 1, wherein the doping element of Group III is indium or gallium, the doping element of Group V is nitrogen, phosphorus, arsenic or antimony, and the doping element of Group VII is chlorine or iodine.

4. The white LED according to claim 1, wherein the II-VI semiconductor compound is a film including (ZnₓCd₁₋ₓ)(O_{y}Se_{z}Te_{1-y-z}).

5. The white LED according to claim 1, wherein the II-VI semiconductor compound is mixed with mono-layer quantum dot or multi-layer quantum dot.

6. A method for forming a white light emitting diode (LED), comprising:
providing a GaN multi-layer structure, the GaN emitting a first wavelength of visible light; and
forming a photon energy conversion layer on the GaN multi-layer structure, the photon energy conversion layer including II-VI semiconductor compounds of (Zn_{z}Cd_{1-z})(O_{y}Se_{z}Te_{1-y-z}) doped with elements of Group III, Group V or Group VII, wherein 0≦x, y, z≦1, the photon energy conversion layer emitting a second wavelength of visible light after absorbing said first wavelength of visible light, such that the first wavelength and the second wavelength are mixed and emitted to a white light, wherein the second wavelength is longer than the first wavelength.

7. The method for forming a white LED according to claim 6, wherein the photon energy conversion layer is formed by using molecular beam epitaxial method or metal organic chemical vapor deposition method.

8. The method for forming a white LED according to claim 6, wherein the doping element of Group III is indium or gallium, the doping element of Group V is nitrogen, phosphorus, arsenic or antimony, the doping element of Group VII is chlorine or iodine.

9. The method for forming a white LED according to claim 6, wherein the II-VI semiconductor compound is a film including (ZnₓCd₁₋ₓ)(O_{y}Se_{z}Te_{1-y-z}).

10. The method for forming a white LED according to claim 6, wherein the II-VI semiconductor compound is mixed with mono-layer quantum dot or multi-layer quantum dot.
